(19) United States
(12) Patent Application Publication
(10) Pub. No.: US 2025/0098112 A1
(43) Pub. Date: Mar. 20, 2025

(54) CONDUCTOR MEMBER WITH COOLING STRUCTURE

(71) Applicant: Yazaki Corporation, Tokyo (JP)

(72) Inventors: Junya HIGASHI, Kakegawa-shi (JP); Hiroyuki TANAKA, Kakegawa-shi (JP); KAZUKI SHIROSAKA, Kakegawa-shi (JP)

(73) Assignee: Yazaki Corporation, Tokyo (JP)

(21) Appl. No.: 18/806,071

(22) Filed: Aug. 15, 2024

(30) Foreign Application Priority Data
Sep. 20, 2023 (JP) 2023-152095

(51) Int. Cl. H05K 7/20; H01B 5/02

(52) U.S. Cl. CPC H05K 7/20272; H01B 5/02; H05K 7/2049

(57) ABSTRACT

A conductor member with a cooling structure includes a cooling pipeline inside which a refrigerant flows, and a conductor member formed by a conductive metal in a band shape, one end side of the conductor member being connected to a component terminal of a predetermined electrical or electronic component, another end side of the conductor member being connected to an electrical connection target of the electrical or electronic component and being configured to be energized, and the cooling pipeline being configured to be fixed so as to be in contact with a connection portion of the conductor member, wherein the connection portion is configured for connection to component terminal.

### BACKGROUND

### Technical Field

The present invention relates to a conductor member with a cooling structure that connects a component terminal of an electrical or electronic component to an electrical connection target while cooling the component terminal.

### Related Art

Conventionally, there has been known a conductor member with a cooling structure in which a cooling function of the conductor member is added to a conductor member that connects a component terminal of an electrical or electronic component to an electrical connection target (see, for example, JP 2018-018661 A). The conductor member with a cooling structure of JP 2018-018661 A has a configuration in which a conductive pipe is used as a conductor member, and both ends thereof are crushed to form a connection portion with a component terminal of an electrical or electronic component and an electrical connection target. The electrical connection is made by the conductive pipe itself and the cooling is made by the refrigerant flowing in the pipe.

Patent Literature 1: JP 2018-018661 A

### SUMMARY

In the conductor member with a cooling structure using the conductive pipe described above, the connection portion formed by crushing the end portion tends to be separated from the refrigerant flowing in the hollow portion. On the other hand, in the conductor member with a cooling structure, heat generation at the connection portion with the component terminal of the electrical or electronic component is higher than other portions. However, since the connection portion tends to be separated from the refrigerant as described above, the above-described conductor member with a cooling structure has a problem that the cooling efficiency for the connection portion is low.

Accordingly, the present invention focuses on the above problem, and an object thereof is to provide a conductor member with a cooling structure capable of efficiently cooling a connection portion of an electrical or electronic component with a component terminal.

In order to solve the above problems, a conductor member with a cooling structure includes a cooling pipeline inside which a refrigerant flows, and a conductor member formed by a conductive metal in a band shape, one end side of the conductor member being connected to a component terminal of a predetermined electrical or electronic component, another end side of the conductor member being configured to be connected to an electrical connection target of the electrical or electronic component to be energized, and the cooling pipeline being configured to be fixed so as to be in contact with a connection portion of the conductor member, wherein the connection portion is configured for connection to the component terminal.

According to the conductor member with a cooling structure described above, it is possible to efficiently cool the connection portion of the electrical or electronic component with the component terminal.

### BRIEF DESCRIPTION OF DRAWINGS

FIG. 1 is a perspective view illustrating a conductor member with a cooling structure according to a first embodiment;

FIG. 2 is a plan view of a connection portion between a component terminal of an electrical or electronic component and a conductor member for the conductor member with a cooling structure illustrated in FIG. 1 as viewed from a direction of an arrow V11 in FIG. 1;

FIG. 3 is a cross-sectional view taken along line V12-V12 in FIG. 1, illustrating a connection portion between a component terminal and a conductor member of the electrical or electronic component illustrated in FIG. 2;

FIG. 4 is a perspective view illustrating two conductor plates constituting the conductor member illustrated in FIGS. 1 to 3 side by side;

FIG. 5 is a perspective view illustrating a conductor member with a cooling structure according to a second embodiment;

FIG. 6 is a perspective view of the conductor member illustrated in FIG. 5 as viewed from each of front and back sides;

FIG. 7 is a perspective view of a conductor member according to a third embodiment as viewed from each of front and back sides;

FIG. 8 is a perspective view illustrating a conductor member with a cooling structure according to a fourth embodiment;

FIG. 9 is a plan view of the conductor member with a cooling structure illustrated in FIG. 8 as viewed from a direction of an arrow V13 in FIG. 8;

FIG. 10 is a perspective view illustrating the conductor member illustrated in FIG. 8;

FIG. 11 is a schematic view illustrating a state in which the cooling pipeline is held by the conductor member illustrated in FIG. 10; and

FIG. 12 is a view illustrating a conductor member with a cooling structure according to a fifth embodiment in a plan view equivalent to FIG. 9.

### DETAILED DESCRIPTION

Hereinafter, an embodiment of a conductor member with a cooling structure will be described. First, a first embodiment will be described.

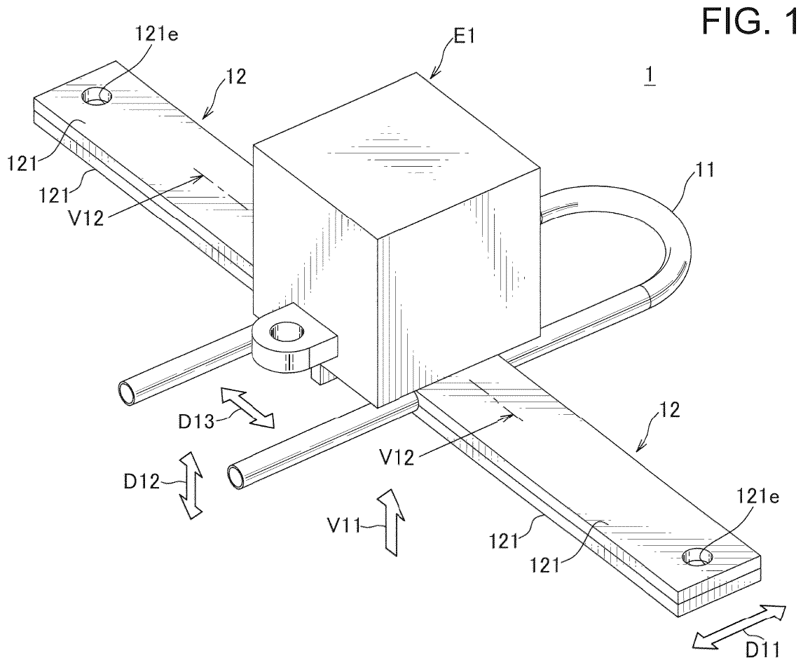

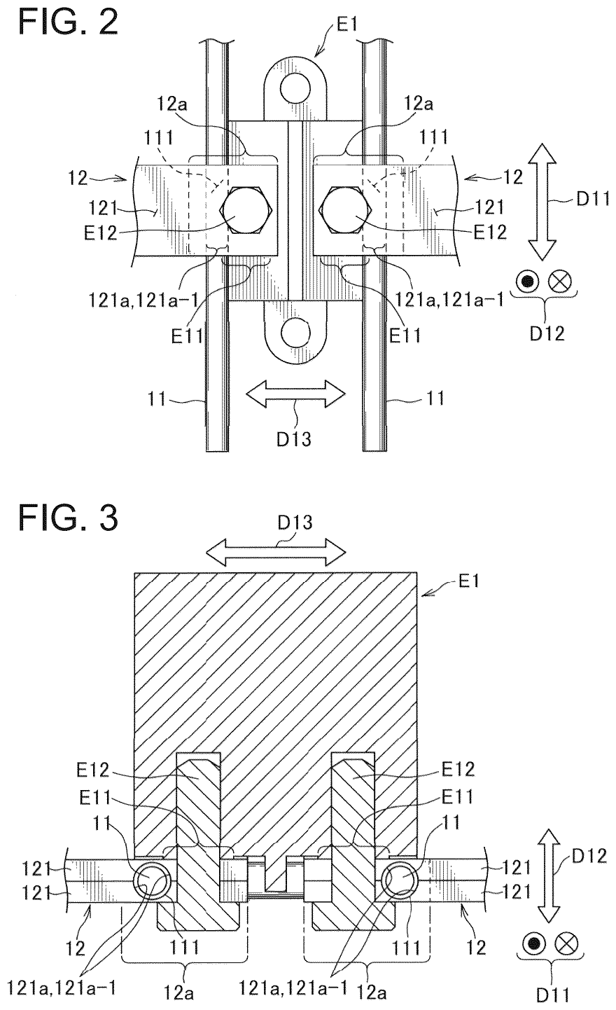

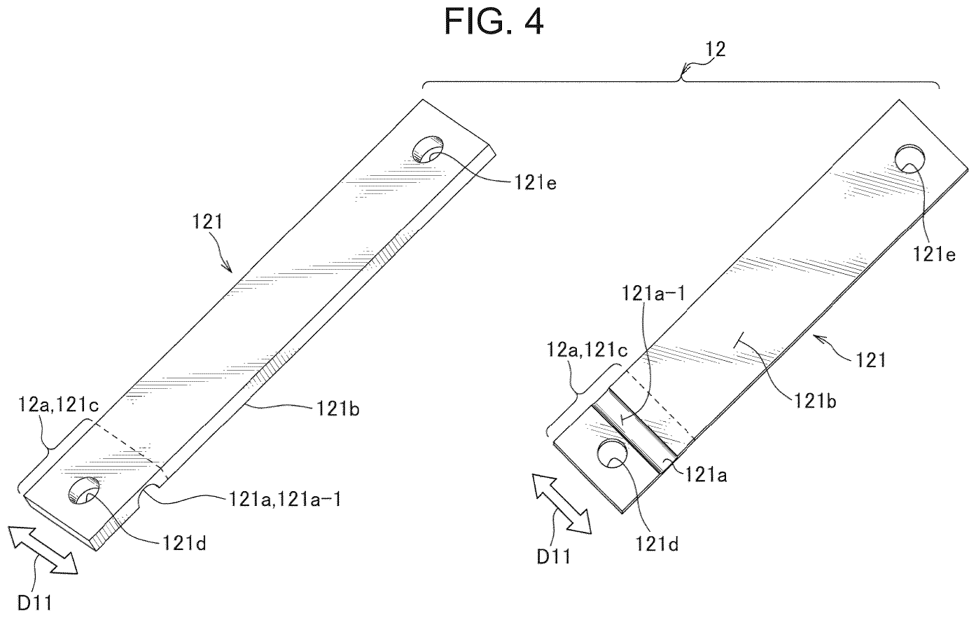

FIG. 1 is a perspective view illustrating a conductor member with a cooling structure according to a first embodiment, and FIG. 2 is a plan view of a connection portion between a component terminal of an electrical or electronic component and a conductor member for the conductor member with the cooling structure illustrated in FIG. 1 as viewed from a direction of an arrow V11 in FIG. 1. Further, FIG. 3 is a cross-sectional view taken along line V12-V12 in FIG. 1, illustrating the connection portion between the component terminal and the conductor member of the electrical or electronic component illustrated in FIG. 2. FIG. 4 is a perspective view illustrating two conductor plates constituting the conductor member illustrated in FIGS. 1 to 3 side by side.

The conductor member 1 with a cooling structure in the present embodiment is a member for connecting each of a pair of component terminals E11 in a relay, which is an electrical or electronic component E1, to an electrical connection target of the electrical or electronic component E1. The conductor member 1 with a cooling structure includes one cooling pipeline 11 and a pair of conductor members 12 connected in a one-to-one manner to the pair of component terminals E11 and to which the cooling pipeline 11 is fixed.

The cooling pipeline 11 is formed by bending one round pipe in a U shape on the way, and a refrigerant flows through the inside. In the present embodiment, water which is a fluid having conductivity is used as the refrigerant. Further, as the cooling pipeline 11, a metal pipeline having conductivity is used. Examples of the metal pipeline include a copper pipeline.

The pair of conductor members 12 is formed by a conductive metal in a band shape, and has one end side connected to the component terminal E11 of the electrical or electronic component E1 and the other end side connected to an electrical connection target and being configured to be energized. Further, the cooling pipeline 11 is fixed to each conductor member 12 by the following structure so as to be in contact with a connection portion 12a of the conductor member 12, wherein the connection portion 12a is configured for connection to the component terminal E11. That is, in the present embodiment, the conductor member 12 has two conductor plates 121 each having a band plate shape and overlapping each other, and the cooling pipeline 11 is sandwiched and fixed by the two conductor plates 121. On each of the two conductor plates 121, a pipeline holding groove 121a that houses the cooling pipeline 11 with respect to a part in a thickness direction D12 thereof, specifically, a half thereof is formed on a facing surface 121b at the time of overlapping, so as to cross the connection portion 12a of the conductor member 12 in a width direction D11.

Further, in the present embodiment, the connection portion 12a of the conductor member 12 is screwed to the component terminal E11 with a screw E12. In each of the two conductor plates 121, a screw through hole 121d for screwing is formed in an end portion 121c corresponding to the connection portion 12a, and the pipeline holding groove 121a is formed adjacent to the screw through hole 121d so as to cross the end portion 121c. Since the cooling pipeline 11 is a round pipe, the pipeline holding groove 121a is a round groove having a semicircular groove cross section. Both a conductor-side contact surface 121a-1, which is a groove inner surface in contact with the cooling pipeline 11, in the pipeline holding groove 121a and a pipeline-side contact surface 111 in contact with the conductor-side contact surface 121a-1 in the cooling pipeline 11 are insulated by insulation coating or the like. Then, the cooling pipeline 11 is fixed to the pipeline holding groove 121a by adhesion or the like, and the two conductor plates 121 are joined to each other by a conductive adhesive, welding, or the like. Note that the joining of the two conductor plates 121 may be adhesive bonding using an insulating adhesive or the like. In this case, one conductor plate 121 in direct contact with the component terminal E11 among the two conductor plates 121 contributes to conduction with the electrical connection target.

Further, in the present embodiment, the other end side of the conductor member 12 is also connected to the electrical connection target by screwing, and a screw through hole 121e for screwing is also formed on the other end side of each conductor plate 121.

In the present embodiment, each of the pair of conductor members 12 is arranged so as to extend in an arrangement direction D13 of the pair of component terminals E11. The cooling pipeline 11 is bent in a U shape between the pipeline holding groove 121a in one conductor member 12 and the pipeline holding groove 121a in the other conductor member 12.

According to the conductor member 1 with a cooling structure of the first embodiment described above, in the conductor member 12, the cooling pipeline 11 is fixed so as to be in contact with the connection portion 12a with the component terminal E11 of the electrical or electronic component E1. By fixing the cooling pipeline 11 at such a position, heat generated at the connection portion 12a with the component terminal E11 is easily transferred to the refrigerant of the cooling pipeline 11, and the connection portion 12a can be efficiently cooled.

Here, in the present embodiment, the refrigerant is water which is a fluid having conductivity, and the cooling pipeline 11 is a metal pipeline having conductivity. Both the conductor-side contact surface 121a-1 in the conductor member 12 and the pipeline-side contact surface 111 of the cooling pipeline 11 are insulated. With this configuration, it is possible to use general water, copper piping, or the like as the conductive refrigerant or the cooling pipeline 11 while preventing the connection portion 12a of the electrical or electronic component E1 to the component terminal E11 from being short-circuited to an unintended location via the refrigerant or the cooling pipeline 11.

Further, in the present embodiment, the conductor member 12 sandwiches and fixes the cooling pipeline 11 between the two conductor plates 121, and in each conductor plate 121, the pipeline holding groove 121a that houses a part of the cooling pipeline 11 inside is formed. With this configuration, by sandwiching the cooling pipeline 11 between the two conductor plates 121 so as to be accommodated in the pipeline holding grooves 121a, the contact area between the cooling pipeline 11 and the conductor member 12 can be increased, and the cooling efficiency can be further enhanced. Further, by sandwiching the cooling pipeline 11 between the two conductor plates 121, the fixing strength of the cooling pipeline to the conductor member 12 can be increased.

Further, in the present embodiment, in each conductor plate 121, the pipeline holding groove 121a is formed so as to cross next to the screw through hole 121d for screwing. With this configuration, the cooling pipeline 11 can be effectively brought into contact with the connection portion 12a connected to the component terminal E11 of the electrical or electronic component E1 by screwing.

Further, in the present embodiment, the cooling pipeline 11 is one pipeline partially fixed to each of the pair of conductor members 12, and is bent in a U shape between the pipeline holding groove 121a of one conductor member 12 and the pipeline holding groove 121a of the other conductor member 12. With this configuration, the pair of connection portions 12a connected to the pair of component terminals E11 in the electrical or electronic component E1 can be efficiently cooled by the single cooling pipeline 11.

Next, a second embodiment will be described. The second embodiment is different from the first embodiment in the configuration of the conductor member. Hereinafter, the second embodiment will be described focusing on differences from the first embodiment.

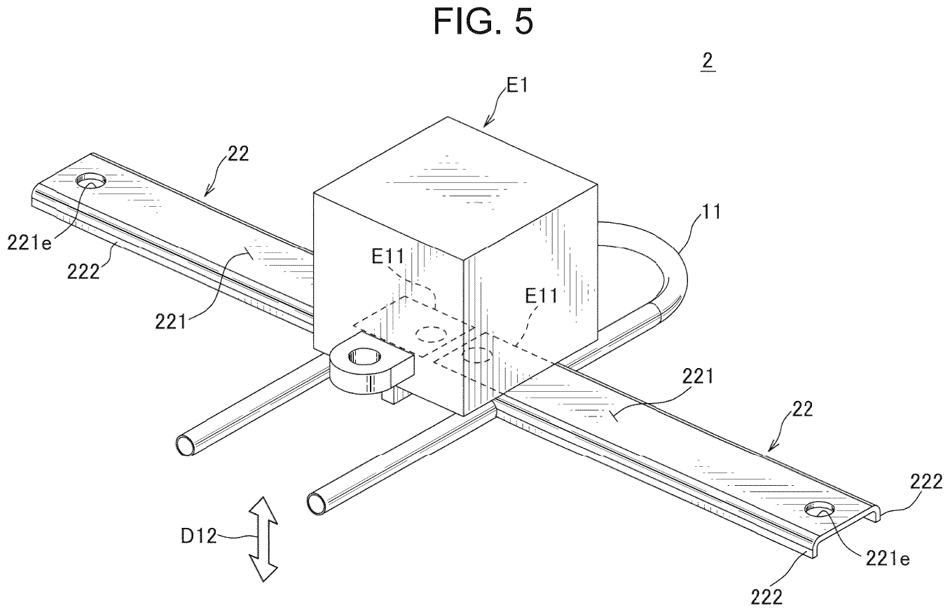

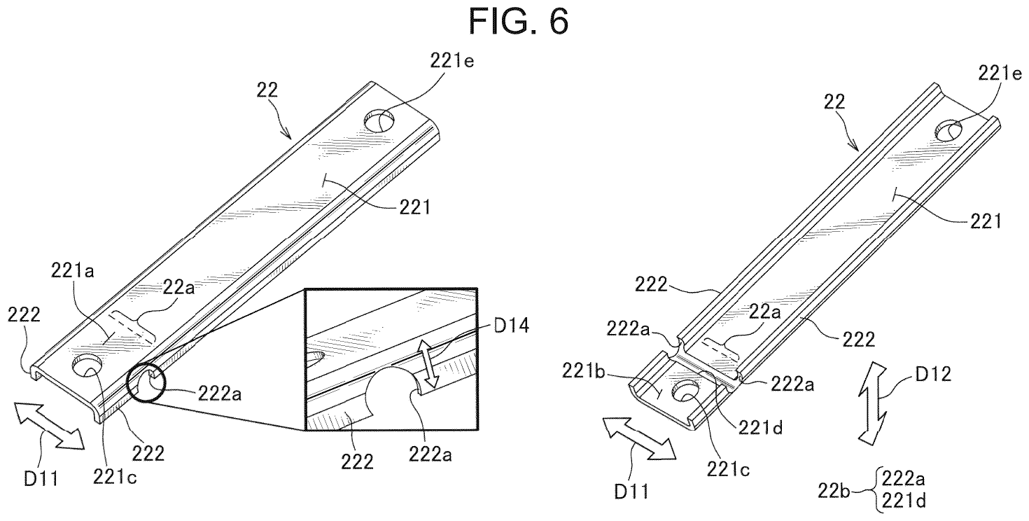

FIG. 5 is a perspective view illustrating a conductor member with a cooling structure according to a second embodiment, and FIG. 6 is a perspective view of the conductor member illustrated in FIG. 5 as viewed from each of front and back sides. Note that, in FIG. 5, components equivalent to the components of the first embodiment illustrated in the perspective view of FIG. 1 are denoted by the same reference numerals as those in FIG. 1 only for the components necessary for the description, and redundant description of the components will be omitted below.

The conductor member 2 with a cooling structure of the second embodiment is similar to that of the first embodiment described above in that the conductor member 2 with a cooling structure includes one cooling pipeline 11 and a pair of conductor members 22 connected in a one-to-one manner to the pair of component terminals E11 of the electrical or electronic component E1 and to which the cooling pipeline 11 is fixed. However, the present embodiment is different from the first embodiment in that the conductor member 22 is one sheet metal member having a band plate portion 221 and a pair of side wall ribs 222.

The band plate portion 221 is a band plate shaped portion in which a connection portion 22a with the component terminal E11 is provided at one end, a screw through hole 221c for screwing is formed in the connection portion 22a, and a screw through hole 221e for screwing to an electrical connection target is also formed on the other end side. The pair of side wall ribs 222 is portions erected on a pair of lateral sides of the band plate portion 221, and in the present embodiment, each side wall rib 222 is formed by sheet metal working in which a side edge portion of a metal strip wider than the band plate portion 221 is bent at a right angle. In each of the pair of side wall ribs 222, a pipeline holding portion 222a through which the cooling pipeline 11 is passed and held so as to cross and contact the connection portion 22a of the band plate portion 221 in the width direction D11. The pipeline holding portion 222a is a portion having a notch shape cut in an arc shape from an end edge of each of the pair of side wall ribs 222. The respective pipeline holding portions 222a of the pair of side wall ribs 222 are formed at positions coaxial with each other in the width direction D11, and a part of the cooling pipeline 11 is fixed so as to penetrate the pair of pipeline holding portions 222a.

Here, in the connection portion 22a of the band plate portion 221, the side of front and back surfaces of the connection portion opposite to the protruding side of the connection portion is a terminal contact surface 221a in contact with the component terminal E11, wherein the pair of side wall ribs 222 protrudes from the protruding side and the protruding side is a pipeline contact surface 221b in contact with the cooling pipeline 11. A pipeline passage groove 221d through which the cooling pipeline 11 passes in a state where a part in the thickness direction D12 of the cooling pipeline 11 is accommodated is formed in the pipeline contact surface 221b in the width direction D11. In each of the pair of side wall ribs 222, a pipeline holding portion 222a is formed at a position where the part of the cooling pipeline 11 is accommodated in the pipeline passage groove 221d in a rib height direction D14. The pipeline passage groove 221d is an arc-shaped round groove in which a groove cross section that receives a part of the round cooling pipeline 11 forms a part of the arc-shaped shape of the pipeline holding portion 222a. The pipeline passage groove 221d and the pair of pipeline holding portions 222a are formed by punching out the pair of side wall ribs 222 while cutting the pipeline contact surface 221b with a predetermined tool.

In the conductor member 22 of the present embodiment, an inner edge of the pipeline holding portion 222a having the cutaway shape in the side wall rib 222 and an inner surface of the pipeline passage groove 221d in the band plate portion 221 constitute a conductor-side contact surface 22b that comes into contact with the cooling pipeline 11. The conductor-side contact surface 22b and the pipeline-side contact surface 111 of the cooling pipeline 11 are each insulated by applying an insulation coating material. Then, the conductor member 22 and the cooling pipeline 11 are fixed by adhesion or the like.

Also by the conductor member 2 with a cooling structure according to the second embodiment described above, it goes without saying that the connection portion 22a of the electrical or electronic component E1 with the component terminal E11 can be efficiently cooled similarly to the first embodiment described above.

Further, in the present embodiment, the conductor member 22 is a portion having the band plate portion 221 and the pair of side wall ribs 222, and the pipeline holding portion 222a having a cutaway shape is formed in each of the pair of side wall ribs 222. With this configuration, the conductor member 22 can have a thin structure of the band plate portion 221 and the pair of side wall ribs 222. With this thin structure, the material cost of the conductor member 22 can be suppressed and the weight of the conductor member 22 can be reduced as compared with the case where the conductor member 22 is formed in a thick plate shape.

Further, in the present embodiment, the pipeline passage groove 221d is formed in the pipeline contact surface 221b of the connection portion 22a of the band plate portion 221. The pipeline holding portion 222a of each side wall rib 222 is formed at a position where a part of the cooling pipeline 11 is accommodated in the pipeline passage groove 221d in the rib height direction D14. With this configuration, the cooling pipeline 11 held by the pipeline holding portion 222a is brought into contact with the pipeline contact surface 221b of the band plate portion 221 so as to be accommodated in the pipeline passage groove 221d, whereby the contact area between the cooling pipeline 11 and the conductor member 22 is increased, and the cooling efficiency can be further enhanced.

Further, in the present embodiment, the cooling pipeline 11 is bent in a U shape between the pipeline holding portion 222a in one of the pair of conductor members 22 connected in a one-to-one manner to the pair of component terminals E11 and the pipeline holding portion 222a in the other. With this configuration, the pair of connection portions 22a connected to the pair of component terminals E11 in the electrical or electronic component E1 can be efficiently cooled by the single cooling pipeline 11.

Next, a third embodiment will be described. The third embodiment is a modification of the second embodiment described above, and the pipeline holding portion of the conductor member is different from that of the second embodiment. Hereinafter, the third embodiment will be described focusing on differences from the second embodiment.

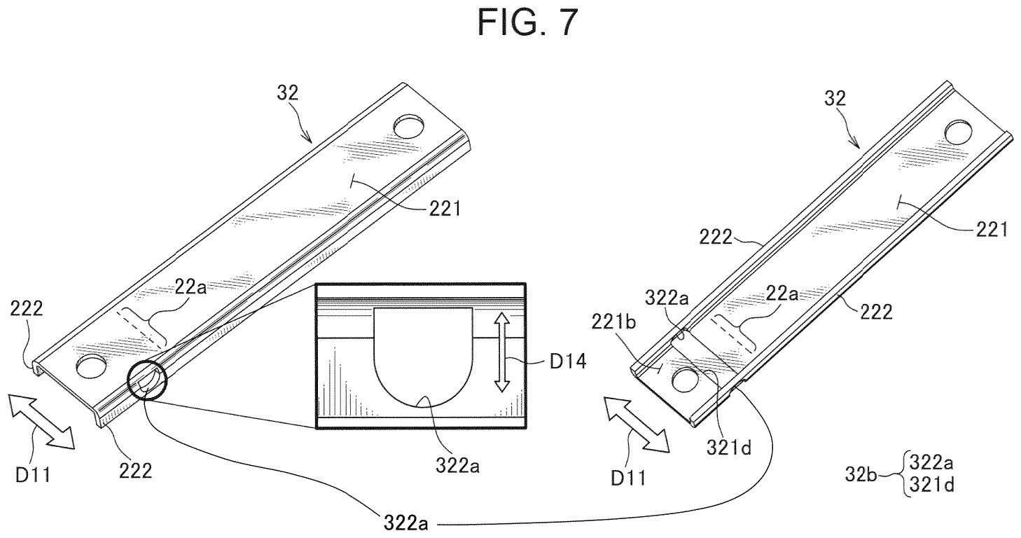

FIG. 7 is a perspective view of a conductor member according to a third embodiment as viewed from each of front and back sides. Note that, in FIG. 7, components equivalent to the components of the second embodiment illustrated in the perspective view of FIG. 6 are denoted by the same reference numerals as those in FIG. 6 only for the components necessary for the description, and redundant description of the components will be omitted below.

A conductor member 32 in the third embodiment is different from that of the second embodiment in the shapes of a pipeline holding portion 322a provided on the pair of side wall ribs 222 and a pipeline passage groove 321d provided on the pipeline contact surface 221b of the connection portion 22a of a band plate portion 221. In the present embodiment, the pipeline holding portion 322a does not have a cutaway shape but has a through hole shape coaxially penetrating the pair of side wall ribs 222. The through hole as the pipeline holding portion 322a has a shape in which a hole portion having a semicircular shape on the end edge side of the side wall rib 222 and a hole portion having a rectangular shape on the band plate portion 221 side are connected in the rib height direction D14. The pipeline passage groove 321d provided in the pipeline contact surface 221b of the connection portion 22a is a portion connected to a rectangular hole portion in the pipeline holding portions 322a at both ends in the width direction D11, and is a rectangular groove having a rectangular groove cross section. Similarly to the second embodiment, the pipeline passage groove 321d and the pair of pipeline holding portions 322a in the present embodiment are also formed by punching out the pair of side wall ribs 222 while cutting the pipeline contact surface 221b with a predetermined tool.

Then, also in the present embodiment, an inner edge of the pipeline holding portion 322a and an inner surface of the pipeline passage groove 321d in the band plate portion 221 form a conductor-side contact surface 32b in contact with the cooling pipeline 11. The conductor-side contact surface 32b and the pipeline-side contact surface 111 of the cooling pipeline 11 are each insulated by applying an insulation coating material. Then, the conductor member 32 and the cooling pipeline 11 are fixed by adhesion or the like.

According to the third embodiment described above, it goes without saying that the connection portion 22a of the electrical or electronic component E1 with the component terminal E11 can be efficiently cooled similarly to the second embodiment described above, that is, similarly to the first embodiment.

Next, a fourth embodiment will be described. The fourth embodiment is different from the first embodiment in a structure for attaching a cooling pipeline to a conductor member. Hereinafter, the fourth embodiment will be described focusing on differences from the first embodiment.

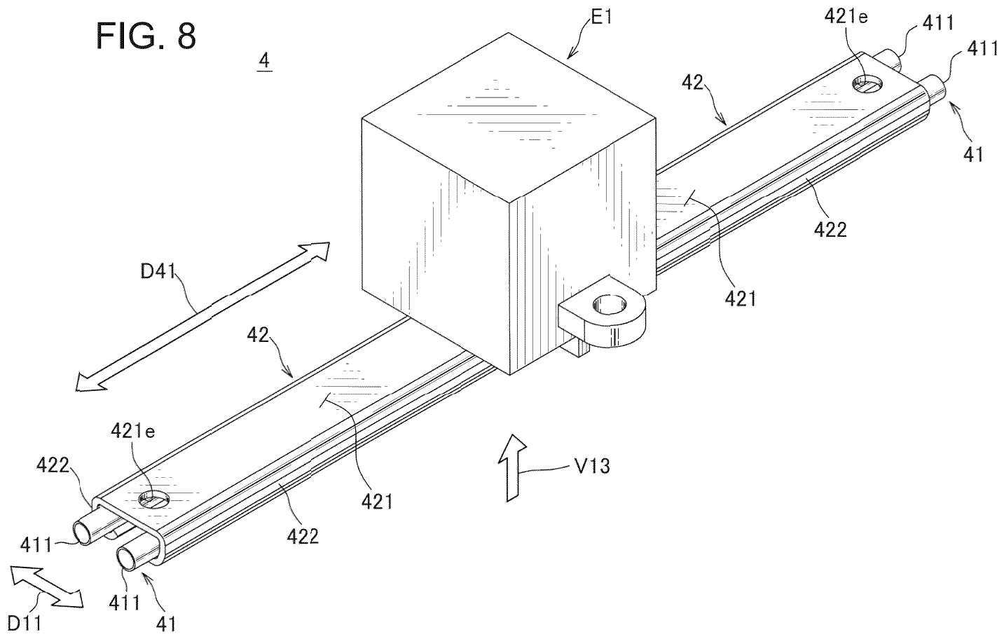

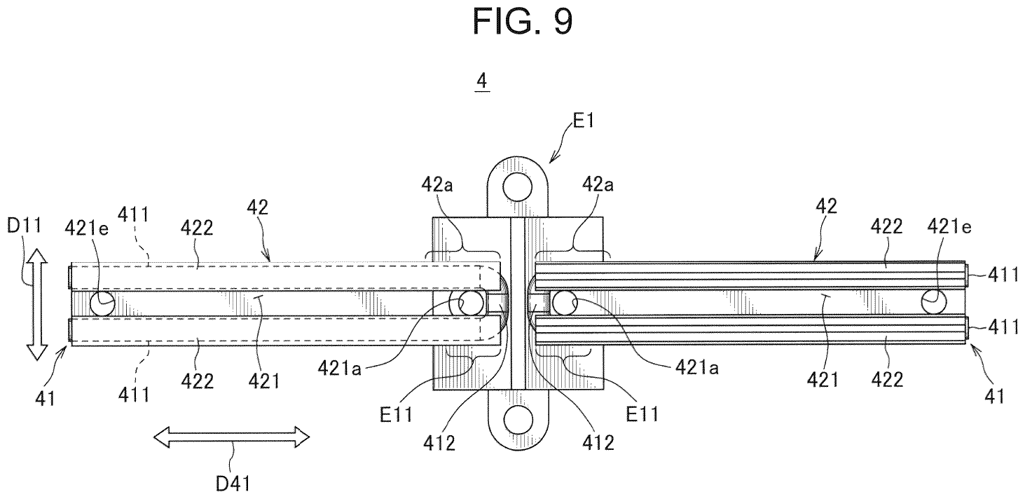

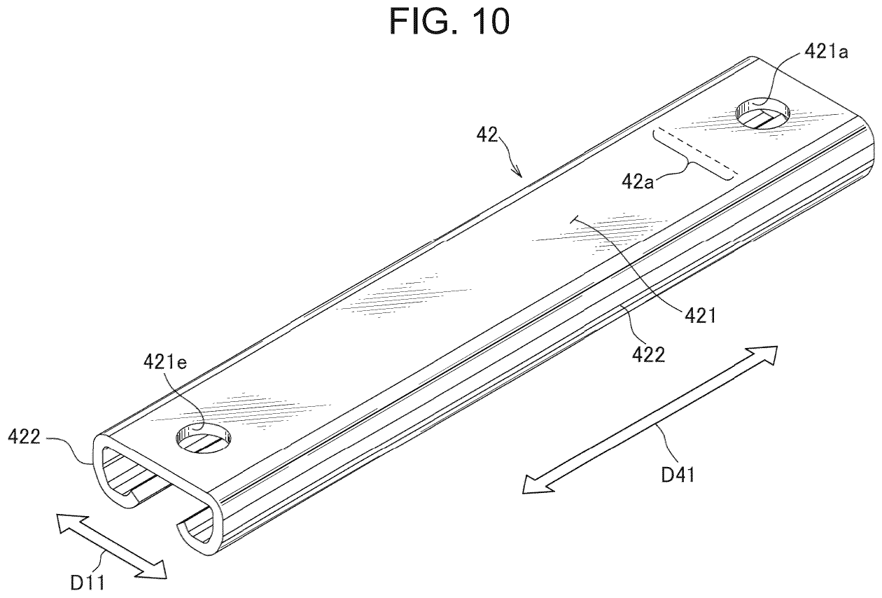

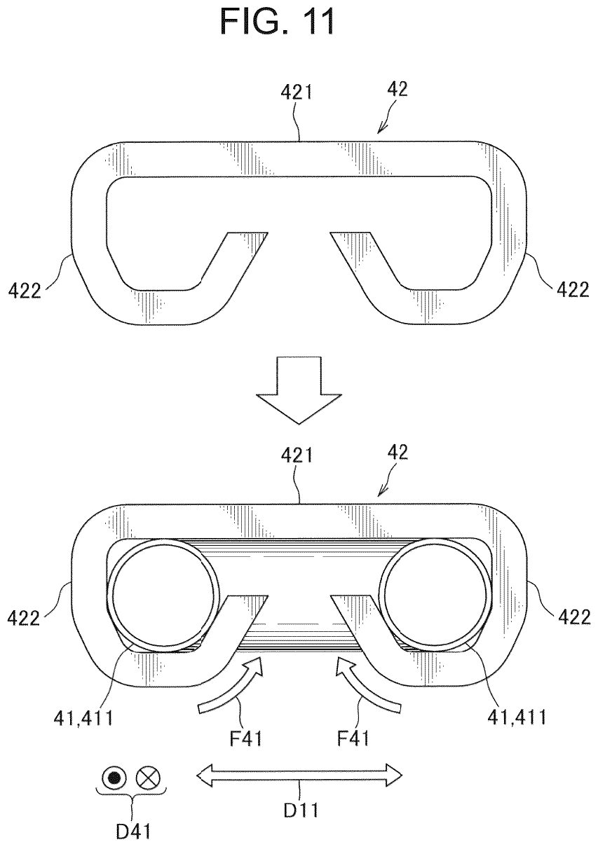

FIG. 8 is a perspective view illustrating a conductor member with a cooling structure according to a fourth embodiment, FIG. 9 is a plan view of the conductor member with a cooling structure illustrated in FIG. 8 as viewed from a direction of an arrow V13 in FIG. 8, and FIG. 10 is a perspective view illustrating the conductor member illustrated in FIG. 8. Further, FIG. 11 is a schematic view illustrating a state in which the cooling pipeline is held by the conductor member illustrated in FIG. 10. Note that, in FIGS. 8 to 10, components equivalent to the components of the first embodiment illustrated in FIGS. 1 to 4 are denoted by the same reference numerals as those in FIGS. 1 to 4 only for the components necessary for the description, and redundant description of the components will be omitted below.

The conductor member 4 with a cooling structure of the fourth embodiment is similar to that of the first embodiment described above in that the conductor member 4 with a cooling structure is a member for connecting each of the pair of component terminals E11 in a relay, which is the electrical or electronic component E1, to the electrical connection target of the electrical or electronic component E1. However, in the present embodiment, one cooling pipeline 41 is attached to each of the pair of conductor members 42 to the pair of component terminals E11 in a one-to-one manner. Each cooling pipeline 41 is fixed in a one to one manner to the conductor member 42 so as to extend at least partially in a length direction D41 of the conductor member 42 while being in contact with a connection portion 42a of each conductor member 42.

Each conductor member 42 includes a band plate portion 421 in which the connection portion 42a with the component terminal E11 is provided at one end, and screw through holes 421a and 421e for screwing are formed on the connection portion 42a and the other end side, and a bending holding portion 422 for fixing the cooling pipeline 41. The bending holding portion 422 is a portion that is erected on both of a pair of lateral sides of the band plate portion 421, is bent toward the center side in the width direction D11 of the band plate portion 421, and sandwiches and holds an extending portion 411 in the length direction D41 of the cooling pipeline 41 with the band plate portion 421.

Then, each cooling pipeline 41 includes a pair of extending portions 411 held by a pair of bending holding portions 422 and a U-shaped bending portion 412. The U-shaped bending portion 412 is a portion in contact with the connection portion 42a while connecting the connection portion 42a side of each of the pair of extending portions 411 so as to surround the screw through hole 421a in a U shape.

In the present embodiment, in the cooling pipeline 41, the pair of extending portions 411 is in contact with the band plate portion 421 and inner surfaces of the pair of bending holding portions 422, and the U-shaped bending portion 412 is in contact with the connection portion 42a. Thus, all of the pair of extending portions 411 and the U-shaped bending portion 412 are insulated by insulation coating. Further, on the conductor member 42 side as well, a surface on the protruding side of the bending holding portion 422 in front and back surfaces of the band plate portion 421 and inner surfaces of the pair of bending holding portions 422 are subjected to insulation processing by insulation coating. Due to these insulating treatments, also in the present embodiment, a conductive metal pipeline such as a copper pipeline is used as the cooling pipeline 41, and water which is a conductive fluid is used as the refrigerant.

Further, in the present embodiment, as illustrated in FIG. 11, the cooling pipeline 41 is strongly pressed against the band plate portion 421 by a spring force F41 derived from the bending structure of the bending holding portion 422. The cooling pipeline 41 is fixed to the conductor member 42 without adhesion or the like by using the spring force F41 in the bending holding portion 422.

According to the fourth embodiment described above, it goes without saying that the connection portion 42a of the electrical or electronic component E1 with the component terminal E11 can be efficiently cooled similarly to the first embodiment described above.

Further, in the present embodiment, the conductor member 42 includes the band plate portion 421 and the bending holding portions 422 provided on both lateral sides of the band plate portion 421 and sandwiching and holding the extending portion 411 of the cooling pipeline 41 in the length direction D41. With this configuration, the contact area between the conductor member 42 and the cooling pipeline 41 can be increased, and the cooling can be efficiently performed. In addition, as illustrated in FIG. 11, since the cooling pipeline 41 is strongly pressed against the band plate portion 421 by the spring force F41 derived from the bending structure of the bending holding portion 422, the cooling efficiency by the cooling pipeline 41 can also be improved in this respect.

Further, in the present embodiment, the cooling pipeline 41 includes the pair of extending portions 411, and the U-shaped bending portion 412 that is in contact with the connection portion 42a while connecting the extending portions 411 so as to surround the screw through hole 421c in a U shape. With this configuration, since the U-shaped bending portion 412 of the cooling pipeline 41 surrounds the periphery of the screw through hole 421c for screwing in the U shape and is in contact with the connection portion 42a, the contact area between the cooling pipeline 41 and the connection portion 42a can be increased to further enhance the cooling efficiency.

Next, a fifth embodiment will be described. The fifth embodiment is a modification of the fourth embodiment described above, and the shape of the cooling pipeline attached to the conductor member is different from that of the fourth embodiment. Hereinafter, the fifth embodiment will be described focusing on differences from the fourth embodiment.

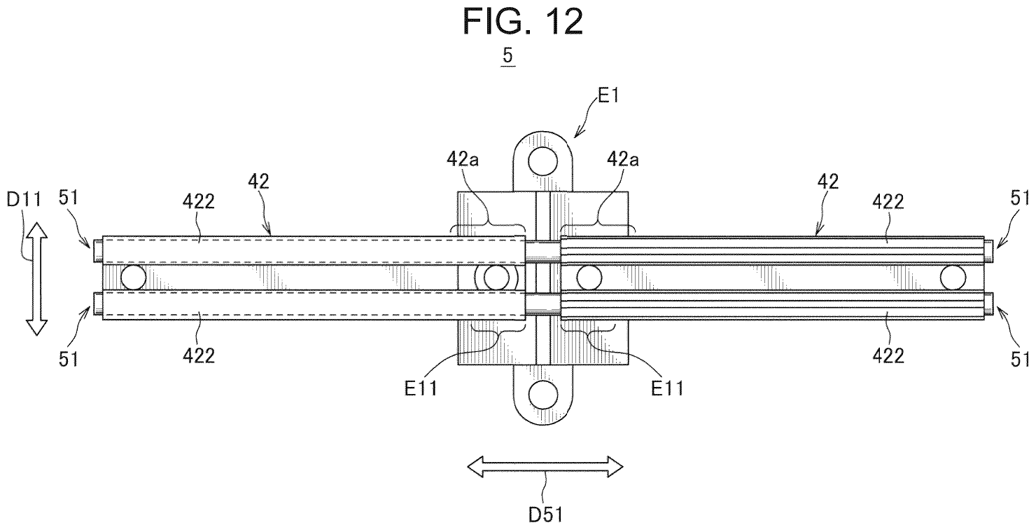

FIG. 12 is a view illustrating a conductor member with a cooling structure according to the fifth embodiment in a plan view equivalent to FIG. 9. Note that, in FIG. 12, components equivalent to the components of the fifth embodiment illustrated in FIGS. 8 to 9 are denoted by the same reference numerals as those in FIGS. 8 to 9 only for the components necessary for the description, and redundant description of the components will be omitted below.

In the conductor member 5 with a cooling structure of the fifth embodiment, two cooling pipelines 51 are attached to each of the pair of conductor members 42 connected in a one-to-one manner to the pair of component terminals E11 of the electrical or electronic component E1 and is similar to the above-described fourth embodiment, so as to be aligned in parallel with the width direction D11. The attached cooling pipelines 51 extend linearly from one to the other of the pair of conductor members 42 and are attached as follows. That is, each cooling pipeline 51 exits the bending holding portion 422 of one conductor member 42, runs straight in an arrangement direction D51 of the pair of component terminals E11 while being in contact with the pair of connection portions 42a, and reaches the bending holding portion 422 of the other conductor member 42. Each cooling pipeline 51 is arranged in this manner and held by the pair of bending holding portions 422.

According to the fifth embodiment described above, it goes without saying that the connection portion 42a of the electrical or electronic component E1 with the component terminal E11 can be efficiently cooled similarly to the first embodiment described above.

Further, in the present embodiment, the cooling pipeline 51 runs straight from the bending holding portion 422 of one conductor member 42 to the bending holding portion 422 of the other conductor member 42 while being in contact with the pair of connection portions 42a on the way. With this configuration, the pair of connection portions 42a connected to the pair of component terminals E11 in the electrical or electronic component E1 can be efficiently cooled together.

Further, in the present embodiment, two cooling pipelines 51 running straight are arranged in parallel in the width direction D11 and are in contact with the pair of connection portions 42a. With this configuration, cooling efficiency can be improved by cooling the pair of connection portions 42a in cooperation with the two cooling pipelines 51.

Note that the first to fifth embodiments described above merely illustrate representative forms of the conductor member with a cooling structure. The conductor member with a cooling structure is not limited thereto, and various modifications can be made.

For example, in the above-described embodiment, as an example of the conductor member with a cooling structure, the conductor members 1, . . . , 5 with a cooling structure for connecting each of the pair of component terminals E11 in a relay, which is the electrical or electronic component E1, to the electrical connection target are exemplified. However, the conductor member with a cooling structure is not limited thereto, and the electrical or electronic component to be connected may be an electrical component other than the relay, or may be another electronic component.

Further, in the embodiment described above, as an example of the conductor member with a cooling structure, the conductor members 1, . . . , 5 with a liquid-cooled cooling structure in which water that is a conductive liquid as a refrigerant flows through the cooling pipelines 11,41, and 51 are exemplified. However, the conductor member with a cooling structure is not limited thereto, and the refrigerant may be a non- conductive liquid or a gas for air cooling.

Further, in the above-described embodiment, as an example of the conductor member with a cooling structure, the conductor members 1, . . . , 5 with a cooling structure including the pair of conductor members 12, . . . , 42 are exemplified. However, the conductor member with a cooling structure is not limited thereto, and may include only one conductor member, three or more conductor members, or the like.

Further, in the above-described embodiment, as an example of the cooling pipeline, round cooling pipelines 11, 41, and 51 constituted by conductive metal pipelines such as copper pipelines are exemplified. However, the cooling pipeline is not limited to this, and may be formed by a non-conductive metal, resin, or the like. The shape of the cooling pipeline may be a square pipe other than a round pipe or another polygonal pipe. In a case where the cooling pipeline is formed by a non-conductive metal, resin, or the like, insulation processing between the cooling pipeline and the conductor member becomes unnecessary.

In addition, in the above-described embodiment, as an example of the conductor member with a cooling structure, the conductor members 1 . . . , 5 with a cooling structure subjected to the following insulation processing are exemplified. That is, the insulation processing here is applied to both the conductor-side contact surfaces 22b and 121a-1 of the conductor members 12, . . . , 42 and the pipeline-side contact surfaces 111 of the cooling pipelines 11, 41, and 51. However, the conductor member with a cooling structure is not limited thereto, and the insulation processing may be performed only on one of the conductor-side contact surface of the conductor member and the pipeline-side contact surface of the cooling pipeline.

Further, in the fourth and fifth embodiments among the above-described embodiments, as an example of the conductor member with a cooling structure, the conductor members 4 and 5 with a cooling structure in which the cooling pipeline s 41 and 51 are held by the bending holding portions 422 on both of the pair of lateral sides of the band plate portion 421 in the conductor member 42 are exemplified. However, the conductor member with a cooling structure is not limited thereto. Even in a case where the bending holding portion is provided in the conductor member, the bending holding portion may be provided only on one of the pair of lateral sides of the band plate portion.

### REFERENCE SIGNS LIST

1, 2, 4, 5 Conductor member with cooling structure
11, 41, 51 Cooling pipeline
12, 22, 32, 42 Conductor member
12a, 22a, 42a Connection portion
22b, 121a-1 Conductor-side contact surface
111 Pipeline-side contact surface
121 Conductor plate
121a Pipeline holding groove
121b Facing surface
121c End portion
121d, 121e, 221c, 221e, 421a, 421e Screw through hole
221, 421 Band plate portion
221a Terminal contact surface
221b Pipeline contact surface
221d, 321d Pipeline passage groove
222 Side wall rib
222a, 322a Pipeline holding portion
411 Extending portion
412 U-shaped bending portion
422 Bending holding portion
D11 Width direction
D12 Thickness direction
D13, D51 Arrangement direction
D14 Rib height direction
D41 Length direction
E1 Electrical or electronic component
E11 Component terminal
E12 Screw
F41 Spring force

What is claimed is:

1. A conductor member with a cooling structure, comprising:
a cooling pipeline inside which a refrigerant flows; and
a conductor member formed by a conductive metal in a band shape, one end side of the conductor member being configured to be connected to a component terminal of a predetermined electrical or electronic component, another end side of the conductor member being configured to be connected to an electrical connection target of the electrical or electronic component to be energized, and the cooling pipeline being configured to be fixed so as to be in contact with a connection portion of the conductor member, wherein the connection portion is configured for connection to the component terminal.

2. The conductor member with a cooling structure according to claim 1, wherein
the refrigerant is a fluid having conductivity, and
the cooling pipeline is a metal pipeline having conductivity, and
at least one of a conductor-side contact surface of the conductor member in contact with the cooling pipeline or a pipeline-side contact surface of the cooling pipeline in contact with the conductor member is insulated.

3. The conductor member with a cooling structure according to claim 1, wherein
the conductor member includes two conductor plates each having a band plate shape and overlapped with each other, and the cooling pipeline is sandwiched and fixed by the two conductor plates, and
on each of the two conductor plates, a pipeline holding groove that houses the cooling pipeline inside with respect to a part in a thickness direction of the cooling pipeline is formed on a facing surface at a time of overlapping, so as to cross the connection portion of the conductor member in a width direction.

4. The conductor member with a cooling structure according to claim 3, wherein
the connection portion of the conductor member is configured to be screwed to the component terminal, and
in each of the two conductor plates, a screw through hole for screwing is formed in an end portion corresponding to the connection portion, and the pipeline holding groove is formed so as to cross the end portion next to the screw through hole.

5. The conductor member with a cooling structure according to claim 3, wherein
the electrical or electronic component is provided with a pair of the component terminals,
a pair of the conductor members is connected in a one-to-one manner to a pair of the component terminals and each of the conductor members is provided so as to extend in an arrangement direction of the component terminals, and
the cooling pipeline is one pipeline partially fixed to each of the pair of conductor members, and is bent in a U shape between the pipeline holding groove in one of the conductor members and the pipeline holding groove in another of the conductor members.

6. The conductor member with a cooling structure according to claim 1, wherein
the conductor member includes a band plate portion in which the connection portion is provided at one end and a pair of side wall ribs erected on a pair of lateral sides of the band plate portion, and
a pipeline holding portion is formed in each of the pair of side wall ribs, the pipeline holding portion having a shape of a through hole through which the cooling pipeline is passed and held so as to cross and contact the connection portion of the band plate portion in a width direction, or a shape of a cutaway from an end edge.

7. The conductor member with a cooling structure according to claim 6, wherein
in the connection portion of the band plate portion, a side of front and back surfaces of the connection portion opposite to a protruding side of the connection portion is a terminal contact surface configured to be in contact with the component terminal, wherein the pair of side wall ribs protrudes from the protruding side and the protruding side is a pipeline contact surface in contact with the cooling pipeline, and
a pipeline passage groove through which the cooling pipeline passes in a state where a part in a thickness direction of the cooling pipeline is accommodated is formed in the pipeline contact surface in the width direction, and
in each of the pair of side wall ribs, the pipeline holding portion is formed at a position where the part of the cooling pipeline is accommodated in the pipeline passage groove in a rib height direction.

8. The conductor member with a cooling structure according to claim 6, wherein the electrical or electronic component is provided with a pair of the component terminals,
a pair of the conductor members is provided so as to be connected in a one-to- one manner to a pair of the component terminals, wherein each of the conductor members is provided so as to extend in an arrangement direction of the component terminals, and
the cooling pipeline is one pipeline partially fixed to each of the pair of conductor members, and is bent in a U shape between the pipeline holding portion in one of the conductor members and the pipeline holding portion in another of the conductor members.

9. The conductor member with a cooling structure according to claim 1, wherein
the cooling pipeline is fixed to the conductor member so that at least a part of the cooling pipeline extends in a length direction of the conductor member while being in contact with the connection portion, and
the conductor member includes
a band plate portion provided with the connection portion at one end, and
a bending holding portion that is erected on at least one of the pair of lateral sides of the band plate portion, is bent toward a center side in a width direction of the band plate portion, and sandwiches and holds an extending portion in the length direction of the cooling pipeline with the band plate portion.

10. The conductor member with a cooling structure according to claim 9, wherein
in the conductor member, a screw through hole through which a screw for screwing passes is formed in the connection portion, the connection portion is configured to be fastened and fixed to the component terminal by screwing, and the bending holding portion is provided on each of the pair of lateral sides, and
the cooling pipeline includes
a pair of extending portions held by a pair of the bending holding portions, and
a U-shaped bending portion that is in contact with the connection portion while connecting sides of the pair of the extending portions each adjacent to the connection portion so as to surround the screw through hole in a U shape.

11. The conductor member with a cooling structure according to claim 9, wherein
in the conductor member, a screw through hole through which a screw for screwing passes is formed in the connection portion, the connection portion is configured to be fastened and fixed to the component terminal by screwing, and the bending holding portion is provided on each of the pair of lateral sides, and
a pair of the cooling pipelines is fixed to the conductor member so that the extending portion is held in a one to one manner by a pair of the bending holding portions and the cooling pipeline runs straight next to the screw through hole and comes into contact with the connection portion.

12. The conductor member with a cooling structure according to claim 9, wherein the electrical or electronic component is provided with a pair of the component terminals,
a pair of the conductor members is connected in a one-to-one manner to a pair of the component terminals and each of the conductor members is provided so as to extend in an arrangement direction of the component terminals, and
the cooling pipeline is held by a pair of the bending holding portions so as to exit the bending holding portion in one of the conductor members, run straight in the arrangement direction while being in contact with a pair of the connection portions, and reach the bending holding portion in another of the conductor members.
